(19) United States
(12) Patent Application Publication
(10) Pub. No.: US 2025/0324784 A1
(43) Pub. Date: Oct. 16, 2025

(54) IMAGE SENSOR STRUCTURE

(71) Applicant: Powerchip Semiconductor Manufacturing Corporation, Hsinchu (TW)

(72) Inventors: Avishek Das, Taipei City (TW); Yu-Chieh Lee, Taipei City (TW); Logeshwaran Venkatesapandian, Hsinchu (TW); Chee-Wee Liu, Taipei City (TW)

(73) Assignee: Powerchip Semiconductor Manufacturing Corporation, Hsinchu (TW)

(21) Appl. No.: 18/636,288

(22) Filed: Apr. 16, 2024

(30) Foreign Application Priority Data
Apr. 10, 2024 (TW) 113113287

(51) Int. Cl. H01L 27/146

(52) U.S. Cl. CPC H10F 39/199; H10F 39/182; H10F 39/802

(57) ABSTRACT

An image sensor structure including a substrate and a pixel structure is provided. The substrate includes a front side and a backside opposite to each other. The pixel structure includes a gate, a dielectric layer, a photodetector, and a floating diffusion region. The gate is located in the substrate. The gate includes a first surface and a second surface opposite to each other. The first surface is closer to the front side than the second surface. The width of the first surface is different from the width of the second surface. The dielectric layer is located between the gate and the substrate. The photodetector is located in the substrate on one side of the gate. The floating diffusion region is located in the substrate between the front side and the photodetector.

### CROSS-REFERENCE TO RELATED APPLICATION

This application claims the priority benefit of Taiwan application serial no. 113113287, filed on Apr. 10, 2024. The entirety of the above-mentioned patent application is hereby incorporated by reference herein and made a part of specification.

### BACKGROUND

### Technical Field

The invention relates to a semiconductor structure, and particularly relates to an image sensor structure.

### Description of Related Art

Currently, the image sensor is widely used in many modern electronic devices (e.g., smart phone or digital camera). However, how to further improve the full well capacity (FWC) and reduce optical crosstalk is the goal of continuous efforts at present.

### SUMMARY

The invention provides an image sensor structure, which can increase the full well capacity and reduce the optical crosstalk, thereby improving the image quality.

The invention provides an image sensor structure, which includes a substrate and a pixel structure. The substrate includes a front side and a backside opposite to each other. The pixel structure includes a gate, a dielectric layer, a photodetector (PD), and a floating diffusion (FD) region. The gate is located in the substrate. The gate includes a first surface and a second surface opposite to each other. The first surface is closer to the front side than the second surface. The width of the first surface is different from the width of the second surface. The dielectric layer is located between the gate and the substrate. The photodetector is located in the substrate on one side of the gate. The floating diffusion region is located in the substrate between the front side and the photodetector.

According to an embodiment of the invention, in the image sensor structure, the cross-sectional shape of the gate may be a trapezoid.

According to an embodiment of the invention, in the image sensor structure, the gate may extend in a direction from the front side toward the backside.

According to an embodiment of the invention, in the image sensor structure, the image sensor structure may be a backside illuminated image sensor (BSI image sensor) structure, and the backside may be a light incident surface.

According to an embodiment of the invention, in the image sensor structure, the pixel structure may be a blue pixel structure.

According to an embodiment of the invention, in the image sensor structure, the width of the second surface may be greater than the width of the first surface.

According to an embodiment of the invention, in the image sensor structure, the image sensor structure may be a backside illuminated image sensor structure, and the backside may be a light incident surface.

According to an embodiment of the invention, in the image sensor structure, the pixel structure may be a green pixel structure.

According to an embodiment of the invention, in the image sensor structure, the width of the second surface may be smaller than the width of the first surface.

According to an embodiment of the invention, in the image sensor structure, the image sensor structure may be a front side illuminated image sensor (FSI image sensor) structure, and the front side may be a light incident surface.

According to an embodiment of the invention, in the image sensor structure, the pixel structure may be a blue pixel structure.

According to an embodiment of the invention, in the image sensor structure, the width of the first surface may be greater than the width of the second surface.

According to an embodiment of the invention, in the image sensor structure, the image sensor structure may be a front side illuminated image sensor structure, and the front side may be a light incident surface.

According to an embodiment of the invention, in the image sensor structure, the pixel structure may be a green pixel structure.

According to an embodiment of the invention, in the image sensor structure, the width of the first surface may be smaller than the width of the second surface.

According to an embodiment of the invention, in the image sensor structure, the photodetector may have a protrusion portion protruding toward the front side.

According to an embodiment of the invention, in the image sensor structure, the top surface of the protrusion portion may be higher than the bottom surface of the floating diffusion region and may be lower than the top surface of the floating diffusion region.

According to an embodiment of the invention, the image sensor structure may further include an isolation structure. The isolation structure is located in the substrate. The photodetector may be located between the gate and the isolation structure.

According to an embodiment of the invention, in the image sensor structure, the isolation structure may extend in a direction from the front side toward the backside.

According to an embodiment of the invention, the image sensor structure may include a plurality of the pixel. The plurality of the pixel structures may share the gate.

Based on the above description, in the image sensor structure according to the invention, since the gate is located in the substrate, the full well capacity can be effectively increased, thereby improving the image quality. In addition, the gate includes the first surface and the second surface opposite to each other, the first surface is closer to the front side than the second surface, and the width of the first surface is different from the width of the second surface. Therefore, for a specific pixel structure (e.g., blue pixel structure or green pixel structure), the optical crosstalk can be reduced by adjusting the width relationship between the first surface of the gate and the second surface of the gate, thereby improving the image quality.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of an image sensor structure according to some embodiments of the invention.

FIG. 2 is a cross-sectional view taken along section line I-I′ in FIG. 1 according to some embodiments of the invention.

FIG. 3 is a cross-sectional view taken along section line I-I′ in FIG. 1 according to other embodiments of the invention.

FIG. 4 is a cross-sectional view taken along section line I-I′ in FIG. 1 according to other embodiments of the invention.

FIG. 5 is a cross-sectional view taken along section line I-I′ in FIG. 1 according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

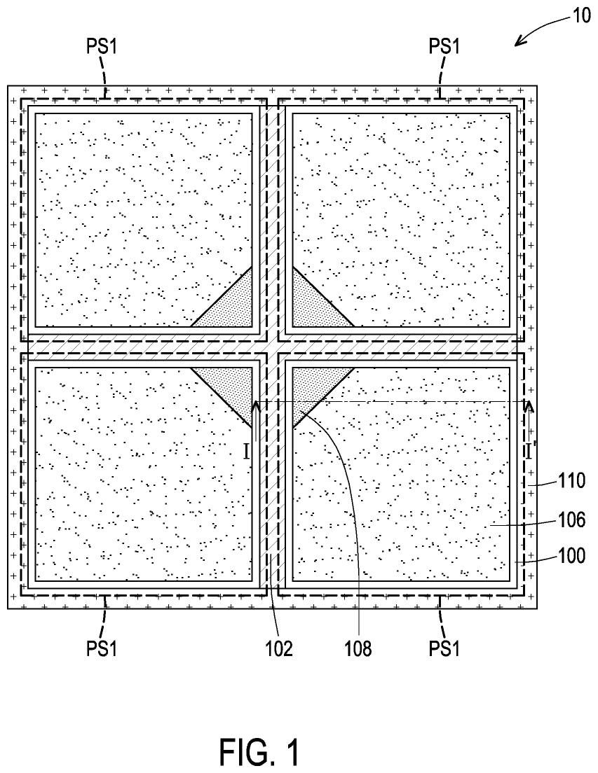

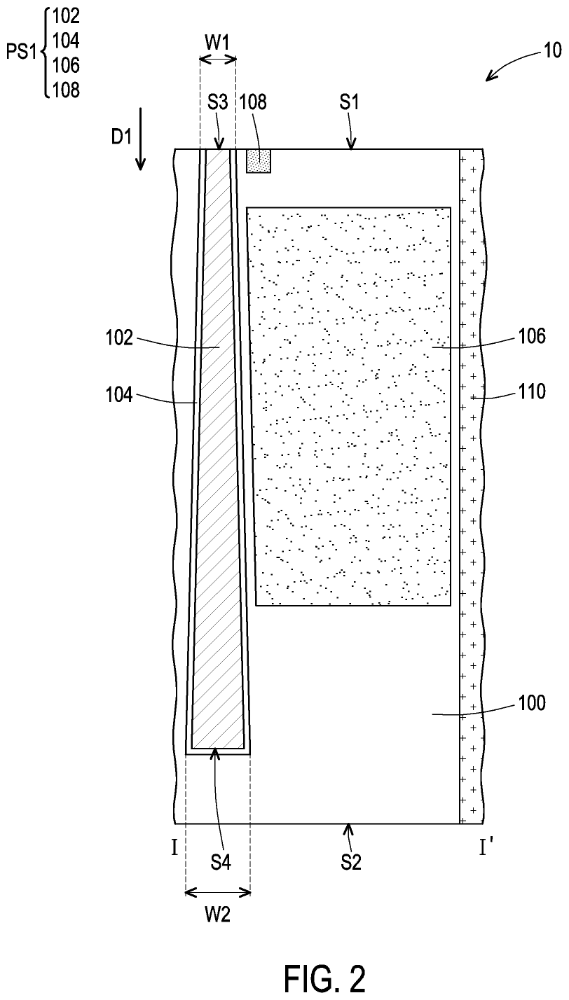

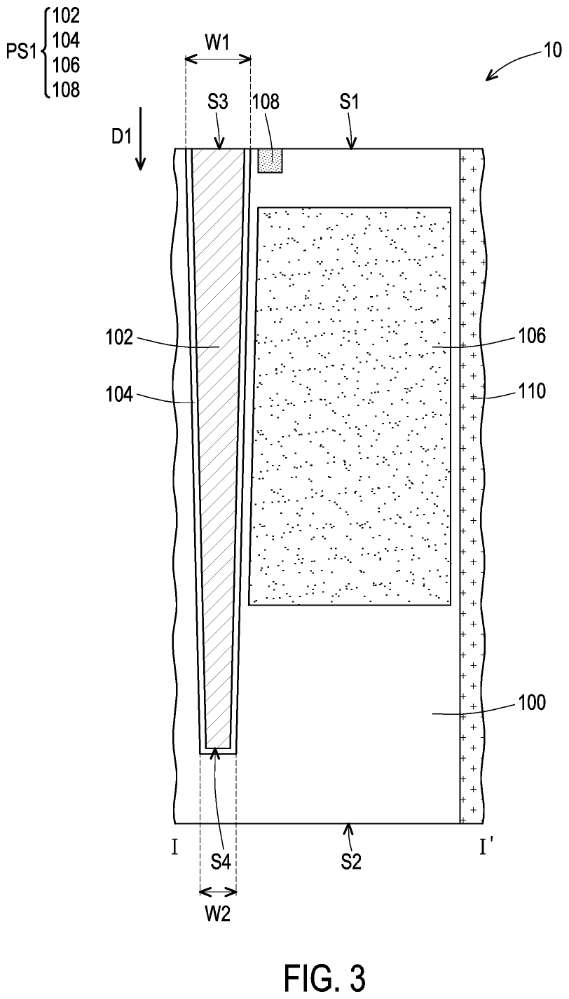

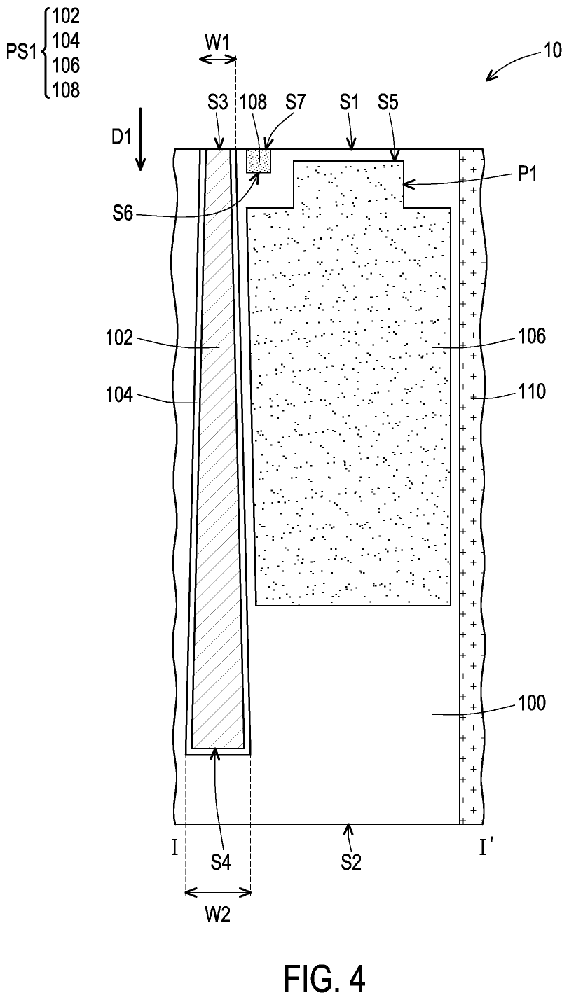

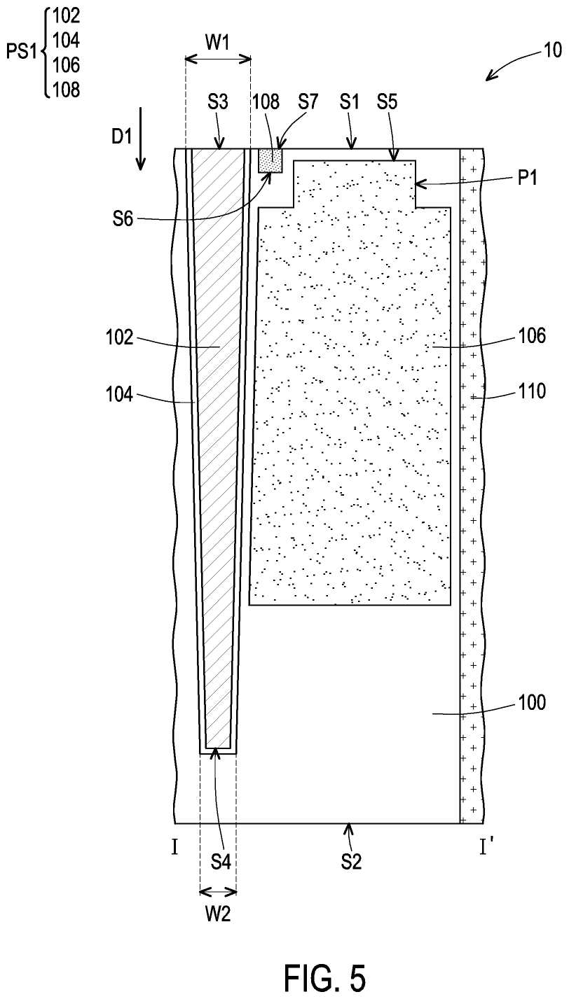

FIG. 1 is a top view of an image sensor structure according to some embodiments of the invention. FIG. 2 is a cross-sectional view taken along section line I-I′ in FIG. 1 according to some embodiments of the invention. In FIG. 1, some components in FIG. 2 are omitted to clearly illustrate the configuration relationship between the components in FIG. 1. FIG. 3 is a cross-sectional view taken along section line I-I′ in FIG. 1 according to other embodiments of the invention. FIG. 4 is a cross-sectional view taken along section line I-I′ in FIG. 1 according to other embodiments of the invention. FIG. 5 is a cross-sectional view taken along section line I-I′ in FIG. 1 according to other embodiments of the invention.

Referring to FIG. 1 and FIG. 2, an image sensor structure 10 includes a substrate 100 and a pixel structure PS1. The substrate 100 includes a front side S1 and a backside S2 opposite to each other. The substrate 100 may be a single-layer structure or a multilayer structure. In some embodiments, the substrate 100 may be a semiconductor substrate. In some embodiments, the substrate 100 may be a silicon substrate, an epitaxial layer, or a combination thereof.

The pixel structure PS1 includes a gate 102, a dielectric layer 104, a photodetector 106, and a floating diffusion region 108. The gate 102 is located in the substrate 100. Since the gate 102 is located in the substrate 100, the full well capacity can be effectively increased, thereby improving the image quality. In some embodiments, the gate 102 may extend in a direction D1 from the front side S1 toward the backside S2. In some embodiments, the cross-sectional shape of the gate 102 may be a trapezoid. The gate 102 may be a single-layer structure or a multilayer structure. In some embodiments, the material of the gate 102 may be a conductive material such as titanium nitride (TiN).

The gate 102 includes a first surface S3 and a second surface S4 opposite to each other. The first surface S3 is closer to the front side S1 than the second surface S4. The width W1 of the first surface S3 is different from the width W2 of the second surface S4. In the present embodiment, as shown in FIG. 2, the width W2 of the second surface S4 may be greater than the width W1 of the first surface S3, but the invention is not limited thereto. In other embodiments, as shown in FIG. 3, the width W2 of the second surface S4 may be smaller than the width W1 of the first surface S3.

In some embodiments, as shown in FIG. 2, the image sensor structure 10 may be a backside illuminated image sensor structure, the backside S2 may be a light incident surface, the pixel structure PS1 may be a blue pixel structure, and the width W2 of the second surface S4 may be greater than the width W1 of the first surface S3, so that the optical crosstalk can be reduced, thereby improving the image quality.

In other embodiments, as shown in FIG. 2, the image sensor structure 10 may be a front side illuminated image sensor structure, the front side S1 may be a light incident surface, the pixel structure PS1 may be a green pixel structure, and the width W1 of the first surface S3 may be smaller than the width W2 of the second surface S4, so that the optical crosstalk can be reduced, thereby improving the image quality.

In some embodiments, as shown in FIG. 3, the image sensor structure 10 may be a backside illuminated image sensor structure, the backside S2 may be a light incident surface, the pixel structure PS1 may be a green pixel structure, and the width W2 of the second surface S4 may be smaller than the width W1 of the first surface S3, so that the optical crosstalk can be reduced, thereby improving the image quality.

In other embodiments, as shown in FIG. 3, the image sensor structure 10 may be a front side illuminated image sensor structure, the front side S1 may be a light incident surface, the pixel structure PS1 may be a blue pixel structure, and the width W1 of the first surface S3 may be larger than the width W2 of the second surface S4, so that the optical crosstalk can be reduced, thereby improving the image quality.

The dielectric layer 104 is located between the gate 102 and the substrate 100. In some embodiments, the material of the dielectric layer 104 is, for example, a dielectric material such as aluminum oxide (Al₂O₃). The photodetector 106 is located in the substrate 100 on one side of the gate 102. In some embodiments, the photodetector 106 may be a photodiode. The floating diffusion region 108 is located in the substrate 100 between the front side S1 and the photodetector 106. In some embodiments, the floating diffusion region 108 may be a doped region.

In other embodiments, compared with the image sensor structure 10 of FIG. 2, the photodetector 106 in the image sensor structure 10 of FIG. 4 may have a protrusion portion P1 protruding toward the front side S1, thereby further increasing the full well capacity. In other embodiments, compared with the image sensor structure 10 of FIG. 3, the photodetector 106 in the image sensor structure 10 of FIG. 5 may have a protrusion portion P1 protruding toward the front side S1, thereby further increasing the full well capacity. In addition, in FIG. 4 and FIG. 5, the top surface S5 of the protrusion portion P1 may be higher than the bottom surface S6 of the floating diffusion region 108 and may be lower than the top surface S7 of the floating diffusion region 108.

Referring to FIG. 1 and FIG. 2, the image sensor structure 10 may further include an isolation structure 110. The isolation structure 110 is located in the substrate 100. The photodetector 106 may be located between the gate 102 and the isolation structure 110. In some embodiments, the isolation structure 110 may extend in the direction D1 from the front side S1 toward the backside S2. In some embodiments, the isolation structure 110 may be a deep trench isolation (DTI) structure, a shallow trench isolation (STI) structure, or a combination thereof. In some embodiments, the isolation structure 110 may be a continuous structure or a discontinuous structure. In some embodiments, the material of the isolation structure 110 may include silicon oxide.

In some embodiments, as shown in FIG. 1, the image sensor structure 10 may include a plurality of the pixel structures PS1. The plurality of the pixel structures PS1 may share the gate 102. In some embodiments, the plurality of the pixel structures PS1 may all be blue pixel structures. In some embodiments, the plurality of the pixel structures PS1 may all be green pixel structures. In some embodiments, the plurality of the pixel structures PS1 may all be red pixel structures. In some embodiments, the plurality of pixel structures PS1 may be any combination of a blue pixel structure, a green pixel structure, and a red pixel structure. In some embodiments, as shown in FIG. 1, the top-view shape of the gate 102 may include a cross shape.

In addition, in the semiconductor structure 10 of FIG. 2 to FIG. 5, the same or similar components are denoted by the same reference symbols, and the description thereof is omitted. Furthermore, although not shown in the figure, the image sensor structure 10 may include required components such as color filter layers, microlenses, and/or required doped regions, and the description thereof is omitted.

Based on the above embodiments, in the image sensor structure 10, since the gate 102 is located in the substrate 100, the full well capacity can be effectively increased, thereby improving the image quality. In addition, the gate 102 includes the first surface S3 and the second surface S4 opposite to each other, the first surface S3 is closer to the front side S1 than the second surface S4, and the width W1 of the first surface S3 is different from the width W2 of the second surface S4. Therefore, for a specific pixel structure PS1 (e.g., blue pixel structure or green pixel structure), the optical crosstalk can be reduced by adjusting the width relationship between the first surface S3 of the gate 102 and the second surface S4 of the gate 102, thereby improving the image quality.

In summary, in the image sensor structure of the aforementioned embodiments, since the gate is located in the substrate, the full well capacity can be effectively increased, thereby improving the image quality. In addition, the gate includes the first surface and the second surface opposite to each other, the first surface is closer to the front side than the second surface, and the width of the first surface is different from the width of the second surface. Therefore, for a specific pixel structure (e.g., blue pixel structure or green pixel structure), the optical crosstalk can be reduced by adjusting the width relationship between the first surface of the gate and the second surface of the gate, thereby improving the image quality.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An image sensor structure, comprising:
a substrate comprising a front side and a backside opposite to each other; and
a pixel structure comprising:
a gate located in the substrate and comprising a first surface and a second surface opposite to each other, wherein the first surface is closer to the front side than the second surface, and a width of the first surface is different from a width of the second surface;
a dielectric layer located between the gate and the substrate;
a photodetector located in the substrate on one side of the gate; and
a floating diffusion region located in the substrate between the front side and the photodetector.

2. The image sensor structure according to claim 1, wherein a cross-sectional shape of the gate comprises a trapezoid.

3. The image sensor structure according to claim 1, wherein the gate extends in a direction from the front side toward the backside.

4. The image sensor structure according to claim 1, wherein the image sensor structure is a backside illuminated image sensor structure, and the backside is a light incident surface.

5. The image sensor structure according to claim 4, wherein the pixel structure is a blue pixel structure.

6. The image sensor structure according to claim 5, wherein the width of the second surface is greater than the width of the first surface.

7. The image sensor structure according to claim 1, wherein the image sensor structure is a backside illuminated image sensor structure, and the backside is a light incident surface.

8. The image sensor structure according to claim 7, wherein the pixel structure is a green pixel structure.

9. The image sensor structure according to claim 8, wherein the width of the second surface is smaller than the width of the first surface.

10. The image sensor structure according to claim 1, wherein the image sensor structure is a front side illuminated image sensor structure, and the front side is a light incident surface.

11. The image sensor structure according to claim 10, wherein the pixel structure is a blue pixel structure.

12. The image sensor structure according to claim 11, wherein the width of the first surface is greater than the width of the second surface.

13. The image sensor structure according to claim 1, wherein the image sensor structure is a front side illuminated image sensor structure, and the front side is a light incident surface.

14. The image sensor structure according to claim 13, wherein the pixel structure is a green pixel structure.

15. The image sensor structure according to claim 14, wherein the width of the first surface is smaller than the width of the second surface.

16. The image sensor structure according to claim 1, wherein the photodetector has a protrusion portion protruding toward the front side.

17. The image sensor structure according to claim 16, wherein a top surface of the protrusion portion is higher than a bottom surface of the floating diffusion region and is lower than a top surface of the floating diffusion region.

18. The image sensor structure according to claim 1, further comprising:
an isolation structure located in the substrate, wherein the photodetector is located between the gate and the isolation structure.

19. The image sensor structure according to claim 18, wherein the isolation structure extends in a direction from the front side toward the backside.

20. The image sensor structure according to claim 1, comprising a plurality of the pixel structures, and the plurality of the pixel structures share the gate.
